(19) United States
(12) Patent Application Publication
(10) Pub. No.: US 2024/0292684 A1
(43) Pub. Date: Aug. 29, 2024

(54) DISPLAY SUBSTRATE, DISPLAY PANEL AND DISPLAY APPARATUS

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Bangqing XIAO, Beijing (CN); Ziyang YU, Beijing (CN); Zhiliang JIANG, Beijing (CN)

(21) Appl. No.: 18/023,763

(22) PCT Filed: Jun. 29, 2022
(86) PCT No.: PCT/CN2022/102173

§ 371 Date: Feb. 28, 2023

(51) Int. Cl. H10K 59/131; H10K 59/121

(52) U.S. Cl. CPC H10K 59/131; H10K 59/1216

(57) ABSTRACT

The present disclosure provides a display substrate, including: a substrate; pixel driving circuits and data lines on the substrate, where at least part of the data lines are connected to different numbers of pixel driving circuits; the display substrate includes first and second conductive layers, the first and second conductive layers and a layer where the data lines are located are sequentially arranged away from the substrate; the first conductive layer includes a first pattern connected to the data lines; orthographic projections of the second conductive layer and the first pattern on the substrate partially overlap with each other; and/or the display substrate further includes a third conductive layer including second patterns, orthographic projections of the second patterns on the substrate overlap with the orthographic projection of the second conductive layer on the substrate, and at least part of the second patterns are connected to the data lines.

### TECHNICAL FIELD

The present disclosure relates to the field of display technology, in particular to a display substrate, a display panel and a display apparatus.

### BACKGROUND

An OLED (Organic Light-Emitting Diode) display apparatus has characteristics of self-luminescence, high brightness, wide viewing angle, high contrast, flexibility, low power consumption, and the like, and thus, has received wide attention, has begun to gradually replace a conventional LCD (Liquid Crystal Display) display apparatus as a new generation of display modes, and is widely applied to mobile phone screens, computer monitors, full-color televisions, and the like.

### SUMMARY

In a first aspect, an embodiment of the present disclosure provides a display substrate, including: a substrate; a plurality of pixel driving circuits arranged in an array on the substrate; and a plurality of data lines arranged, on the substrate, in sequence along a first direction and each extending along a second direction, where each data line is connected to a column of pixel driving circuits; at least part of the plurality of data lines are connected to different numbers of pixel driving circuits, respectively; the display substrate includes a first conductive layer and a second conductive layer, and the first conductive layer, the second conductive layer and a layer where the plurality of data lines are located are sequentially arranged away from the substrate and insulated from each other; the first conductive layer includes a first pattern connected to the data lines; and an orthographic projection of the second conductive layer on the substrate partially overlaps with an orthographic projection of the first pattern on the substrate; and/or the display substrate further includes a third conductive layer between the second conductive layer and the layer where the plurality of data lines are located, and the third conductive layer is insulated from the second conductive layer and the plurality of data lines; and the third conductive layer includes a plurality of second patterns, orthographic projections of the plurality of second patterns on the substrate overlaps with an orthographic projection of the second conductive layer on the substrate, and at least part of the plurality of second patterns are connected to the data lines.

In some implementations, each of the plurality of pixel driving circuits includes a storage capacitor, the second conductive layer includes a plurality of third patterns; the first conductive layer further includes a plurality of fourth patterns; orthographic projections of the third patterns on the substrate at least at least partially overlap with orthographic projections of the fourth patterns on the substrate; each third pattern is common to an electrode plate of the storage capacitor; each fourth pattern is common to another electrode plate of the storage capacitor; and the first pattern is between any two adjacent fourth patterns in the first direction; orthographic projections of the third patterns on the substrate at least partially overlap with the orthographic projection of the first pattern on the substrate.

In some implementations, the first pattern has a stripe shape, and a long side of the first pattern extends in the second direction.

In some implementations, the orthographic projection of the first pattern on the substrate overlaps with orthographic projections of the plurality of data lines on the substrate.

In some implementations, the first conductive layer further includes a plurality of first signal lines; the plurality of first signal lines are sequentially arranged along the second direction and each extend along the first direction; the plurality of first signal lines spatially crosses the plurality of data lines; and orthographic projections of the plurality of first signal lines on the substrate do not overlap with the orthographic projection of the first pattern on the substrate.

In some implementations, numbers of pixel driving circuits connected to different data lines are different from each other; a load of the data line connected to a maximum number of pixel driving circuits is a target load; a plurality of first patterns are provided; each data line without the target load is correspondingly connected to multiple first patterns; an effective total length of the first patterns connected to the data line without the target load, is proportional to a load to be compensated for the data line; the effective total length of the first patterns is a sum of effective lengths of the first patterns; the effective length of each first pattern is a length of an area, in which the orthographic projection of the first pattern on the substrate overlaps with the orthographic projection of the third pattern corresponding to the first pattern on the substrate, along the second direction; the load to be compensated for the data line is a difference between the target load and an actual load of the data line; and the actual load is a load formed by the pixel driving circuits connected to the data line.

In some implementations, the first conductive layer further includes a fifth pattern, an orthographic projection of the fifth pattern on the substrate is located at ends of at least part of the plurality of data lines; the second conductive layer further includes a sixth pattern, and an orthographic projection of the sixth pattern on the substrate is located at ends of at least part of the plurality of data lines; orthographic projections of the fifth pattern and the sixth pattern on the substrate overlap with each other; and the fifth pattern or the sixth pattern is connected to the data lines.

In some implementations, the plurality of second patterns are in a one-to-one correspondence with the plurality of third patterns; and orthographic projections of the second patterns on the substrate overlap with orthographic projections of the third patterns on the substrate.

In some implementations, a shape of each second pattern includes an inverted L shape.

In some implementations, the display substrate further includes a plurality of seventh patterns, the plurality of seventh patterns and the plurality of data lines are located in a same layer, and the plurality of seventh patterns are connected to the plurality of data lines; an insulating layer is arranged between a layer where the plurality of data lines are located and the third conductive layer; each seventh pattern extends along the first direction from the data line connected to the seventh pattern into an area in which orthographic projections of the seventh pattern and the second pattern corresponding to the seventh pattern on the substrate overlap with each other; and the seventh pattern and the second pattern corresponding to each other are connected to each other through a first via in the insulating layer in the area in which the orthographic projections of the seventh pattern and the second pattern on the substrate overlap with each other.

In some implementations, the display substrate further includes a plurality of power supply lines and a plurality of eighth patterns, the plurality of power supply lines and the plurality of eighth patterns are located in the same layer as the plurality of data lines, and each eighth pattern is connected to the power supply line corresponding thereto; the plurality of power supply lines are sequentially arranged along the first direction and each extend along the second direction; each eighth pattern extends along the first direction from the power supply line connected to the eighth pattern into an area in which orthographic projections of the eighth pattern and the second pattern, corresponding the eighth pattern, not connected to the data line on the substrate overlap with each other; and the eighth pattern and the second pattern, corresponding the eighth pattern, not connected to the data line are connected to each other through a second via in the insulating layer in the area in which the orthographic projections of the eighth pattern and the second pattern not connected to the data line on the substrate overlap with each other.

In some implementations, the display substrate further includes an active layer between the substrate and the first conductive layer, the active layer and the first conductive layer are insulated from each other; an orthographic projection of the active layer on the substrate partially overlaps with orthographic projections of the plurality of seventh patterns and the plurality of data lines on the substrate; and the second conductive layer further includes ninth patterns connected to the third patterns, and orthographic projections of the ninth patterns on the substrate overlap with an area in which the orthographic projection of the active layer on the substrate overlaps with the orthographic projections of the plurality of seventh patterns and the plurality of data lines on the substrate.

In some implementations, the display substrate further includes an active layer between the substrate and the first conductive layer, the active layer and the first conductive layer are insulated from each other; an orthographic projection of the active layer on the substrate partially overlaps with orthographic projections of the plurality of data lines on the substrate; and the second conductive layer further includes ninth patterns connected to the third patterns, and each ninth pattern extends along the first direction from a position, at which the eighth pattern and the second pattern corresponding to each other are connected to each other, into an area in which the orthographic projections of the data lines on the substrate overlap with the orthographic projection of the active layer on the substrate, so that an orthographic projection of the ninth pattern on the substrate overlaps with the area in which the orthographic projections of the data lines on the substrate overlap with the orthographic projection of the active layer on the substrate.

In some implementations, each ninth pattern is between two adjacent third patterns along the first direction, and connects the two adjacent third patterns along the first direction.

In a second aspect, an embodiment of the present disclosure further provides a display panel, which includes the display substrate described above.

In a third aspect, an embodiment of the present disclosure further provides a display apparatus, which includes the display panel described above.

### BRIEF DESCRIPTION OF DRAWINGS

The accompanying drawings, which are provided for further understanding of embodiments of the present disclosure and constitute a part of this specification, are for explaining the present disclosure together with the embodiments of the present disclosure, but are not intended to limit the present disclosure. The above and other features and advantages will become more apparent to ordinary skills in the art by describing in detail exemplary embodiments with reference to the drawings. In the drawings:

FIG. 1 is a schematic top view of a circular OLED watch dial in the related art.

FIG. 2 is a schematic diagram illustrating a distance between a compensation capacitance area and a frame connection line in a frame area of a circular OLED watch dial in the related art.

FIG. 3a is a schematic top view of a part of a structure of a display substrate according to an embodiment of the present disclosure.

FIG. 3b illustrates a layout of a part of a first conductive layer according to an embodiment of the present disclosure.

FIG. 3c illustrates a layout of a part of a second conductive layer according to an embodiment of the present disclosure.

FIG. 3d illustrates a layout of a part of a conductive layer where data lines are located according to an embodiment of the present disclosure.

FIG. 4 is a cross-sectional view of a structure taken along a line AA′ of FIG. 3a.

FIG. 5a is a schematic top view of a part of a structure of another display substrate according to an embodiment of the present disclosure.

FIG. 5b illustrates a layout of a part of a third conductive layer according to an embodiment of the present disclosure.

FIG. 5c illustrates another layout of a part of a second conductive layer according to an embodiment of the present disclosure.

FIG. 5d illustrates another layout of a part of a conductive layer where data lines are located according to an embodiment of the present disclosure.

FIG. 5e is an enlarged top view of a location where a seventh pattern is disposed on a display substrate according to an embodiment of the present disclosure.

FIG. 5f is an enlarged top view of a location where an eighth pattern is disposed on a display substrate according to an embodiment of the present disclosure.

FIG. 5g illustrates a layout of a part of an active layer in a pixel driving circuit according to an embodiment of the present disclosure.

FIG. 6 is a cross-sectional view of a structure taken along a line BB′ in FIG. 5a.

### DETAIL DESCRIPTION OF EMBODIMENTS

In order to enable ordinary skills in the art to better understand the technical solutions of the embodiments of the present disclosure, a display substrate, a display panel and a display apparatus according to embodiments of the present disclosure will be described in further detail with reference to the accompanying drawings and implementations.

The embodiments of the present disclosure will be described more fully hereinafter with reference to the accompanying drawings, but the embodiments shown may be embodied in different forms and should not be construed as limited to the embodiments set forth herein. Rather, these embodiments are provided so that the present disclosure will be thorough and complete, and will fully convey the scope of the present disclosure to ordinary skills in the art.

The embodiments of the present disclosure are not limited to the embodiments shown in the drawings, but include modifications of configurations formed based on a manufacturing process. Thus, areas illustrated in the drawings have schematic properties, and shapes of the areas shown in the drawings illustrate specific shapes of the areas of elements, but are not intended to be limiting.

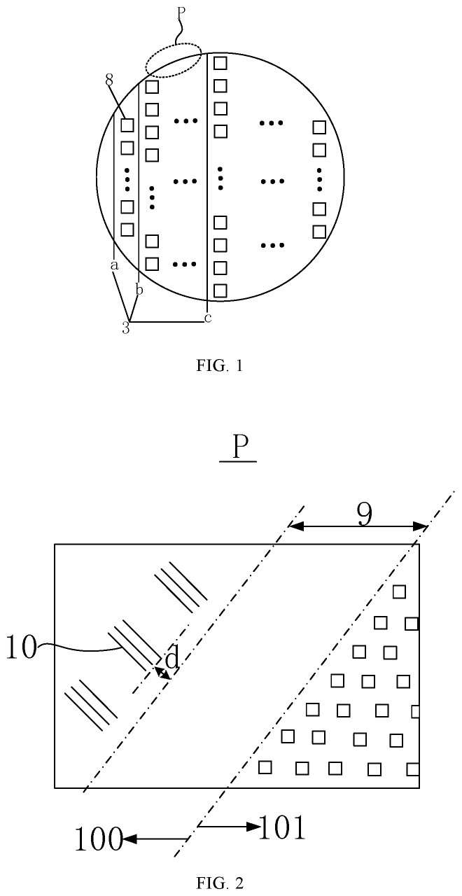

FIG. 1 is a schematic top view of a circular OLED watch dial in the related art. FIG. 2 is a schematic diagram illustrating a distance between a compensation capacitance area and a frame connection line in a frame area (an area P) of a circular OLED watch dial in the related art. As shown in FIGS. 1 and 2, the circular dial is provided with OLED pixel units 8 arranged in an array and a plurality of data lines 3 sequentially arranged in a row direction (in which a row of the array extends) of the array. Each data line 3 extends in a column direction (in which a column of the array extends) of the array and is located between two adjacent columns of OLED pixel units 8. Each data line 3 is used to drive one column of OLED pixel units 8 to display. As shown in FIG. 1, on the circular dial, a length of the c^{th} data line 3 is greater than a length of the b^{th} data line 3, which is in turn greater than a length of the a^{th} data line 3. By taking the resolution of the circular dial being 450×450 as an example, the number of the OLED pixel units 8 in the first column is 30, that is, the first data line 3 drives 30 OLED pixel units 8 to display; the number of the OLED pixel units 8 in the middle column is 450, that is, the middle data line 3 drives 450 OLED pixel units 8 to display. A load difference between the first data line 3 and the middle data line 3 is 420 OLED pixel units 8. In order to ensure that loads of the data lines 3 on the circular dial are the same and the display effect is consistent at different positions on the OLED watch dial, it is desired to provide a compensation capacitance area 9 (an area where compensation capacitors are provided) in a frame area 100 (located at the periphery of a display area 101) of the dial for compensating the loads of the data lines 3. However, the compensation capacitance area 9 is provided in the frame area 100 such that the compensation capacitance area 9 occupies a width of the frame area 100, especially at 450 positions (points) in an upper semicircle of the frame area of the circular dial (i.e., an included angle between a connection line connecting each of the positions with a center of the circular dial and the horizontal line is about 45°); and a distance d of the compensation capacitance area 9 away from a frame connection line 10 (a frame line on a side of a GOA circuit close to the display area) at each 45° position is small, which adversely affects narrowing of the frame of the dial, and thus, adversely affects a narrow frame design of the OLED watch.

In addition, in the design of an FDC watch (having a camera under a screen), a capacitance of a data line is increased due to wire wrapping design for the camera under the screen, so that it is desired to provide a greater number of compensation capacitors in the frame area of the dial, which further adversely affect the narrow frame design of the dial, and is unfavorable for promoting product competitiveness.

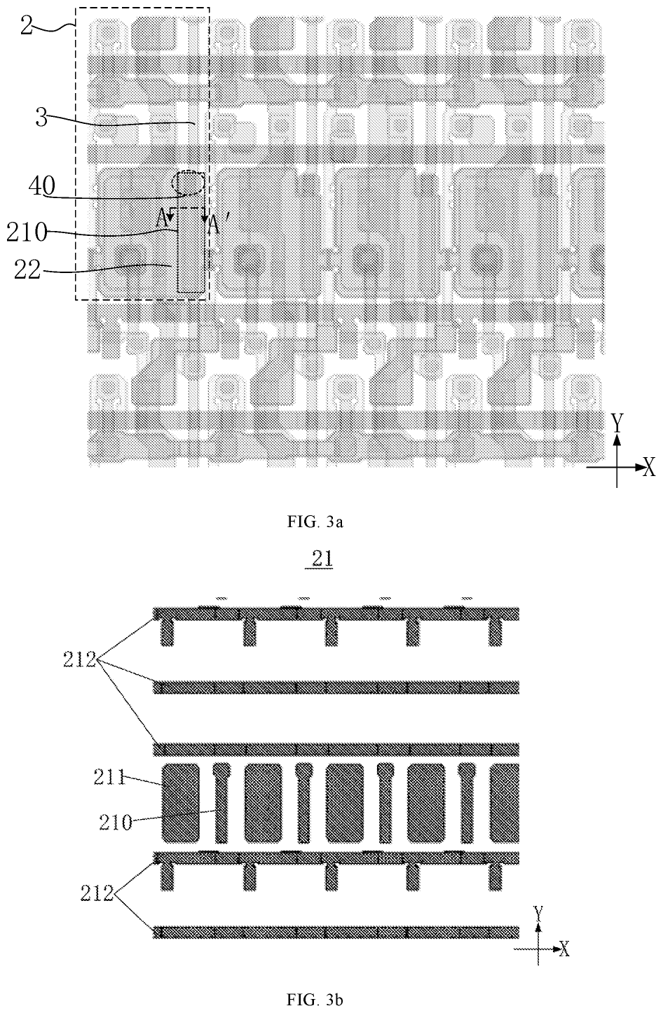

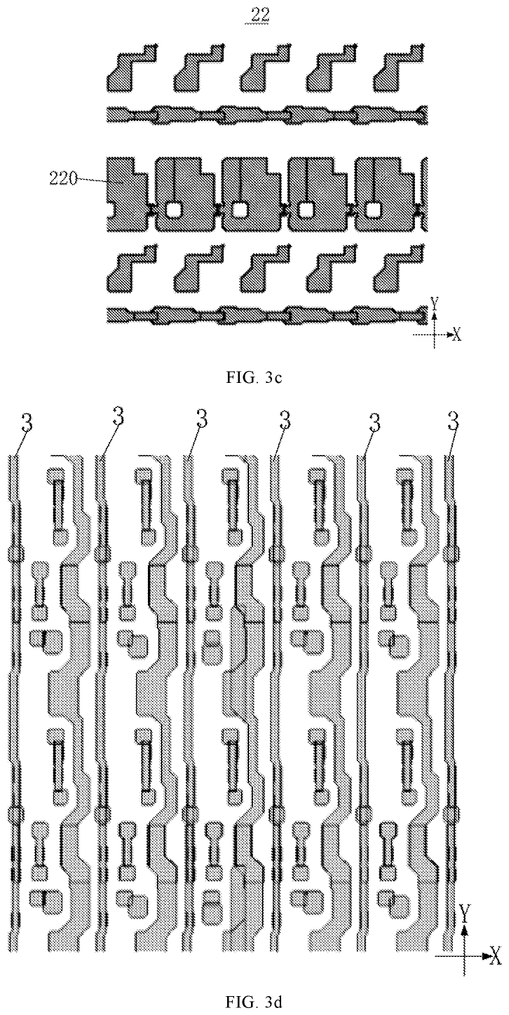

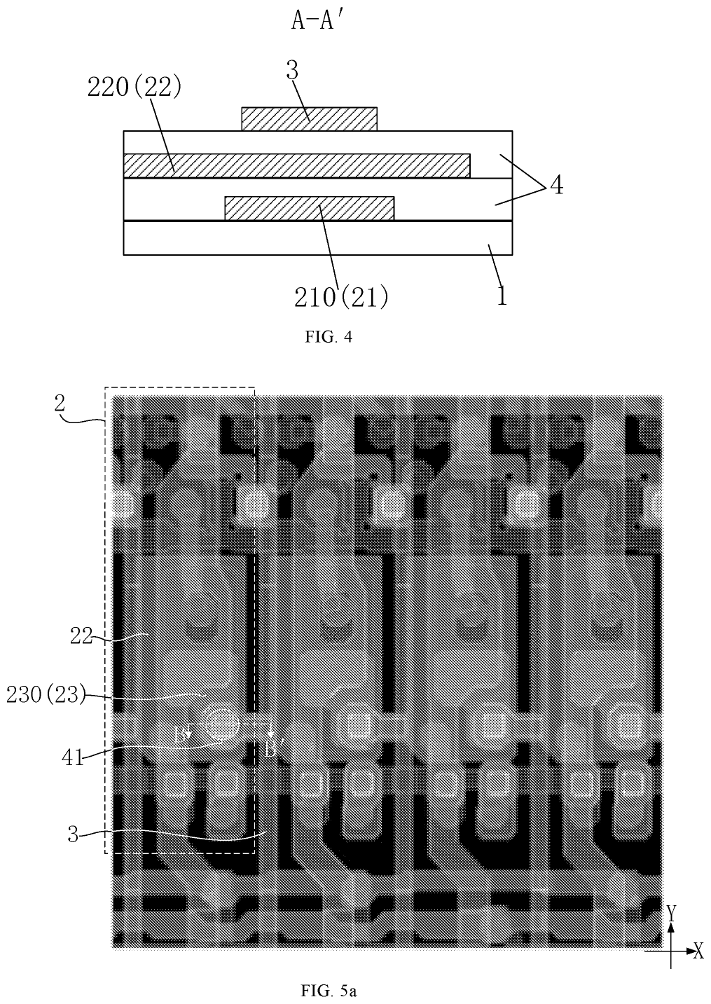

In view of above problems in the related art, in a first aspect, an embodiment of the present disclosure provides a display substrate, referring to FIG. 3a, FIG. 3b, FIG. 3c, FIG. 3d, and FIG. 4. FIG. 3a is a schematic top view of a part of a structure of a display substrate according to an embodiment of the present disclosure. FIG. 3b illustrates a layout of a part of a first conductive layer according to an embodiment of the present disclosure. FIG. 3c illustrates a layout of a part of a second conductive layer according to an embodiment of the present disclosure. FIG. 3d illustrates a layout of a part of a conductive layer where data lines are located according to an embodiment of the present disclosure. FIG. 4 is a cross-sectional view of a structure taken along a line AA′ of FIG. 3a. The display substrate includes: a substrate 1; a plurality of pixel driving circuits 2 arranged in an array on the substrate 1; a plurality of data lines 3 arranged in sequence along a first direction X and each extending along a second direction Y on the substrate 1; each data line 3 is connected to one column of pixel driving circuits 2; at least part of the data lines 3 are respectively connected to different numbers of the pixel driving circuits 2. The display substrate includes a first conductive layer 21 and a second conductive layer 22, and the first conductive layer 21, the second conductive layer 22 and a layer where the data lines 3 are located are sequentially arranged away from the substrate 1 and insulated from each other; the first conductive layer 21 includes a first pattern 210 connected to the data lines 3; an orthographic projection of the second conductive layer 22 on the substrate 1 partially overlaps with an orthographic projection of the first pattern 210 on the substrate 1.

At least part of the data lines 3 are respectively connected to different numbers of pixel driving circuits 2. That is, in the embodiment of the present disclosure, the display area of the display substrate does not have a regular rectangular shape, for example, the display area of the display substrate has a circular shape, an ellipse shape, a polygonal shape, or any other irregular shape; the shape of the display area may result in that at least part of the data lines 3 are respectively connected to different numbers of pixel driving circuits 2, thereby causing a difference between loads of the at least part of the data lines 3. An insulating layer 4 is arranged between any adjacent two of the first conductive layer 21, the second conductive layer 22 and the layer where the data lines 3 are located; orthographic projections of the data lines 3 on the substrate 1 at least partially overlap with orthographic projections of the first patterns 210 on the substrate 1; and the data line 3 and the first pattern 210 are connected to each other in a corresponding overlapping area (in which orthographic projections of the data line 3 and the first pattern 210 overlap with each other) through a via 40 formed in the insulating layer 4.

In some implementations, the first conductive layer 21 further includes patterns of a gate electrode of a transistor in the pixel driving circuit 2, a gate line, a light emitting control line, a reset control line, an electrode plate of a storage capacitor, connection lines between gate electrodes, and the like. The second conductive layer 22 mainly includes a pattern of another electrode plate of the storage capacitor in the pixel driving circuit 2.

In the embodiment, at least part of the data lines 3 are respectively connected to different numbers of pixel driving circuits 2, thereby causing a difference between the loads of the at least part of the data lines 3 in the display substrate. The first pattern 210 is connected to the data line 3, and the orthographic projection of the second conductive layer 22 on the substrate 1 partially overlaps with the orthographic projection of the first pattern 210 on the substrate 1, so that the second conductive layer 22 and the first pattern 210 can form a capacitor in the area where orthographic projections of the first pattern 210 and the second conductive layer 22 overlap with each other, and the capacitor can be used as a load compensation capacitor for compensating the loads of the data lines 3. In this way, on one hand, compensation capacitors for compensating the loads of the data lines 3 in the frame area of the display substrate can be reduced or eliminated, and further, the narrow frame, the ultra-narrow frame or the frameless design of the display substrate can be realized, and the market competitiveness of the display substrate can be improved; on the other hand, the loads of the data lines 3 respectively connected to different numbers of pixel driving circuits 2 on the display substrate tend to be consistent with each other, thereby ensuring that the display effect is consistent at different positions of the display substrate, and ensuring the display effect of the display substrate.

In some implementations, referring to FIGS. 3b and 3c, each of the pixel driving circuits 2 includes a storage capacitor, and the second conductive layer 22 includes a plurality of third patterns 220; the first conductive layer 21 further includes a plurality of fourth patterns 211; orthographic projections of the third patterns 220 on the substrate 1 at least partially overlap with orthographic projections of the fourth patterns 211 on the substrate 1; each third pattern 220 is used as an electrode plate of the storage capacitor; each fourth pattern 211 is used as another electrode plate of the storage capacitor; the first pattern 210 is located between any two adjacent fourth patterns 211 in the first direction X; the orthographic projections of the third pattern 220 on the substrate 1 at least partially overlap with the orthographic projection of the first pattern 210 on the substrate 1. Thus, the third patterns 220 and the first pattern 210 form load compensation capacitors for compensating the loads of the data line 3 connected to the first pattern 21 in the area where the orthographic projections of the third pattern 20 on the substrate 1 overlap with the orthographic projection of the first pattern 210.

In some implementations, the first direction X is a row direction of the array of the pixel driving circuits 2, and the second direction Y is a column direction of the array of the pixel driving circuits 2.

In some implementations, the first pattern 210 has a stripe shape, and a long side of the first pattern 210 extends in the second direction Y.

In some implementations, referring to FIG. 3a, the orthographic projection of the first pattern 210 on the substrate 1 overlaps with the orthographic projections of the data lines 3 on the substrate 1. In this way, the first pattern 210 is easily connected to the data line 3 through the via 40 in the insulating layer 4.

In some implementations, referring to FIG. 3b, the first conductive layer 21 further includes a plurality of first signal lines 212 sequentially arranged along the second direction Y and each extending along the first direction X; the first signal lines 212 spatially crosses the data lines 3 (the first signal lines 212 crosses over the data lines 3; or orthographic projections of the first signal lines 212 on the substrate 1 overlap with orthographic projections of the data lines 3 on the substrate 1); orthographic projections of the first signal lines 212 on the substrate 1 do not overlap with the orthographic projection of the first pattern 210. In this way, it is ensured that the first pattern 210 is an independent pattern that can only be connected to the data lines 3 for compensating the loads of the data lines 3.

In some implementations, the plurality of first signal lines 212 include gate lines, light emitting control lines, and reset control lines.

In some implementations, referring to FIG. 3a, the numbers of pixel driving circuits 2 connected to different data lines 3 are different; the load of the data line 3 connected to a maximum number of pixel driving circuits 2 is a target load; a plurality of the first patterns 210 are included; each data line 3 without the target load is correspondingly connected to multiple first patterns 210; an effective total length of the first patterns 210, connected to the data line 3 without the target load, is proportional to a load to be compensated for the data line 3; the effective total length of the first patterns 210 is a sum of effective lengths of the first patterns 210; the effective length of each first pattern 210 is a length of an area, in which orthographic projections of the first pattern 210 and the third pattern 220 corresponding to each other on the substrate 1 overlap with each other, along the second direction Y; the load to be compensated for the data line 3 is a difference between the target load and an actual load of the data line 3; the actual load is a load formed by the pixel driving circuits 2 connected to the data line 3.

The number of the pixel driving circuits 2 connected to any one of the plurality of data lines 3 is different from the number of the pixel driving circuits 2 connected to any another one of the plurality of data lines 3, that is, the loads of the plurality of data lines 3 are different from each other. The load of the data line 3 with the target load is not to be compensated; the loads of all of the data lines 3 without the target load are to be compensated. In order to ensure the uniformity of the display effect of the display substrate, the load of each data line 3 without the target load is to be compensated to the target load. In the embodiment, each data line 3 without the target load is connected to a the first patterns 210 for compensating the load of data line 3. The first pattern 210 has the stripe shape, and the orthographic projections of the first pattern 210 and the data line 3 corresponding to each other on the substrate 1 overlap with each other. That is, the first pattern 210 actually has a line-like shape, and a width of the first pattern 210 along the first direction X is actually small, so that a value of the effective length of the first pattern 210 directly determines a compensation value for compensating the load of the data line 3. The effective total length of the first patterns 210 connected to each data line 3 without the target load is proportional to the load to be compensated for the data line 3, so that the load of each data line 3 without the target load can be compensated to the target load, the consistency of the display effect of the display substrate can be ensured, an no additional compensation capacitor is desired to be provided in the frame area of the display substrate. Further, it is avoided that the frame area of the display substrate cannot be narrowed due to the presence of any additional compensation capacitor, the narrow frame, the ultra-narrow frame or the frameless design of the display substrate can be realized, and the market competitiveness of the display substrate can be improved.

In the embodiment, the load of each data line 3 can be calculated by the following formula (1).

Cunit×Ndata=Cdata_total (1)

Ndata is the number of pixel units connected to each data line 3; Cunit is a capacitance for each pixel unit; Cdata_total is a total capacitance for each data line 3; Cdata_total may represent the load of each data line 3. Each pixel unit includes a pixel driving circuit 2 and a light emitting element driven by the pixel driving circuit 2 to emit light; the pixel driving circuit 2 in the pixel unit is a main component constituting the load of the data line 3. Cunit may represent a load formed by each pixel unit, and Cunit may also represent a load formed by each pixel driving circuit 2.

In some implementations, the scheme of the display substrate shown in FIG. 3a is adopted. For example, the display substrate has a circular display area, and a resolution of 450×450. The data line 3 connected to the 225^{th} column of pixel driving circuits 2 is longest, and is connected to 450 pixel driving circuits 2 in total; if a capacitance of each pixel driving circuit 2 in the column is 29.9 fF, a total capacitance of the data line 3 connected to the 225^{th} column of pixel driving circuits 2 is 13.455 pF. By adjusting the effective length of the first pattern 210, the maximum effective length of the first pattern 210 can ensure that a capacitance of each pixel driving circuit 2 reaches 70 fF; by adjusting the effective length of the first pattern 210, a capacitance of each pixel driving circuit 2 in the 25^{th} column is 67 fF, and a total capacitance of the data line 3 connected to the 25^{th} column of pixel driving circuits 2 reaches 13.455 pF; thereby eliminating the additional capacitance compensation for the data line 3 connected to the 25^{th} column of pixel driving circuits 2. Similarly, by adjusting the effective length of the first pattern 210, a capacitance of each pixel driving circuit 2 in the 50^{th} column is 47 fF, and a total capacitance of the data line 3 connected to the 50^{th} column of pixel driving circuits 2 reaches 13.455 pF; thereby eliminating the additional capacitance compensation for the data line 3 connected to the 50^{th} column of pixel driving circuits 2; by adjusting the effective length of the first pattern 210, a capacitance of each pixel driving circuit 2 in the 120^{th} column is 33 fF, and a total capacitance of the data line 3 connected to the 120^{th} column of pixel driving circuits 2 reaches 13.455 pF; thereby eliminating the additional capacitance compensation for the data line 3 connected to the 120^{th} column of pixel driving circuits 2. The first pixel driving circuit 2 at an upper end in the 120^{th} column of pixel driving circuits 2 and the first pixel driving circuit 2 at an upper end in the 345^{th} column of pixel driving circuits 2 are approximatively located at left and right 45° positions (points) in the upper semicircle of the circular display area (that is, an included angle between a connection line connecting each of the positions, at which the pixel driving circuits 2 are located in the upper semicircle of the circular area, with a center of the circular area and the horizontal line extending along the first direction X is about 45°). The loads of the data lines 3 connected to the 120^{th} column and the 345^{th} column of pixel driving circuits 2 each can be completely compensated through the first patterns 210, so that the loads of the data lines 3 connected to the 120^{th} column and the 345^{th} column of pixel driving circuits 2 are not to be compensated through additional compensation capacitors. Thus, no compensation capacitor is to be provided at positions in the frame area of the display substrate corresponding to the 120^{th} column and the 345^{th} column of pixel driving circuits 2, the problem in the related art that the frame cannot be further narrowed at such two positions of the frame area of the dial is solved, and the narrow frame, the ultra-narrow frame or the frameless design of the display substrate can be realized.

In some implementations, the first conductive layer further includes a fifth pattern (not shown), an orthographic projection of the fifth pattern on the substrate is located at ends of at least part of the data lines; the second conductive layer further includes a sixth pattern (not shown in the figure), and an orthographic projection of the sixth pattern on the substrate is located at ends of at least part of the data lines; orthographic projections of the fifth pattern and the sixth pattern on the substrate overlap with each other; the fifth pattern or the sixth pattern is connected to the data lines.

The fifth pattern and the sixth pattern form a capacitor in an area in which the orthographic projections of the fifth pattern and the sixth pattern overlap with each other, and the capacitor can be used as a load compensation capacitor for compensating the loads of the data lines 3 connected to the fifth pattern or the sixth pattern. On the basis of compensating for the loads of the data lines 3 by providing the first patterns 210, if the loads of the data lines 3 cannot be compensated completely only through the first patterns 210, the loads of the data lines 3 can be further compensated through the capacitor formed by the fifth pattern and the sixth pattern. In this way, on one hand, compensation capacitors for compensating the loads of the data lines 3 in the frame area of the display substrate can be reduced, and further, the narrow frame or the ultra-narrow frame of the display substrate can be realized, and the market competitiveness of the display substrate can be improved; on the other hand, the loads of the data lines 3 connected to different numbers of pixel driving circuits 2 on the display substrate tend to be consistent with each other, thereby ensuring that the display effect is consistent at different positions of the display substrate, and ensuring the display effect of the display substrate.

In some implementations, the orthographic projections of the fifth and sixth patterns on the substrate are correspondingly located at the ends of the data lines to be compensated through the fifth and sixth patterns, thereby facilitating connections between the data lines and the fifth or sixth pattern. In some implementations, the fifth pattern and the sixth pattern are located in the frame area of the display substrate. The frame area of the display substrate is located at the periphery of the display area, the display area of the display substrate may be circular, ellipse, polygonal or any other irregular shape, and the shape of the display area may result in that at least part of the data lines are respectively connected to different numbers of pixel driving circuits, thereby causing a difference between the loads of the at least part of the data lines.

In some implementations, the load of each data line 3 may be calculated by the following equation (2).

$$Cunit \times Nd ata + Cdata\_compensation = Cdata\_total \qquad ( 2 )$$

Cdata_compensation is the load compensation capacitor formed by the fifth pattern and the sixth pattern; Ndata is the number of pixel units connected to each data line 3; Cunit is a capacitance for each pixel unit; Cunit may represent a load formed by each pixel unit, and Cunit may also represent a load formed by each pixel driving circuit 2; Cdata_total is a total capacitance for each data line 3; Cdata_total may represent the load of each data line 3.

In some implementations, on the basis of compensating for the loads of the data lines 3 in the display substrate by providing the first patterns 210, part of the data lines 3 are to be compensated through the load compensation capacitor formed by the fifth pattern and the sixth pattern. For example, the display substrate has a circular display area, and a resolution of 450×450. The data line 3 connected to the 225^{th} column of pixel driving circuits 2 is longest, and is connected to 450 pixel driving circuits 2 in total; if a capacitance of each pixel driving circuit 2 in the column is 29.9 fF, a total capacitance of the data line 3 connected to the 225^{th} column of pixel driving circuits 2 is 13.455 pF. By adjusting the effective length of the first pattern 210 through the formula (2), the maximum effective length of the first pattern 210 can ensure that a capacitance of each pixel driving circuit 2 reaches 70 fF; by adjusting the effective length of the first pattern 210, a capacitance of each pixel driving circuit 2 in the first column is 70 fF, and a total capacitance of the data line connected to the first column of pixel driving circuits 2 is 2.1 pF; on the premise that each load compensation capacitor formed by the fifth pattern and the sixth pattern is 29.9 fF, 379 load compensation capacitors formed by the fifth pattern and the sixth pattern are desired to be provided for the data line connected to the first column of pixel driving circuits 2 so that the total capacitance of the data line reaches 13.455 pF. In the scheme of the related art in which the compensation is not performed by providing the first patterns, 420 load compensation capacitors formed by the fifth pattern and the sixth pattern are desired to be provided for the data line 3 connected to the first column of pixel driving circuits 2 so that the total capacitance of the data line reaches 13.455 pF. Thus, compared with the scheme of the related art, in the scheme according to the embodiment of the present disclosure, the load compensation capacitors are formed by providing the first patterns 210, the fifth pattern and the sixth pattern, a width of the frame area of the display substrate can be reduced by 105 μm.

Moreover, at the 45° positions (points) at top left and right corners in the upper semicircle of the circular display area of the display substrate, that is, at the positions corresponding to the 120^{th} column and 345^{th} column of pixel driving circuits 2, at which it is difficult to further narrow the frame, by adopting the calculation compensation scheme in the formula (1), the load compensation can be completely performed through the first patterns 210, and the compensation is not to be performed by additional load compensation capacitors formed by the fifth pattern and the sixth pattern any more. Thus, a possibility of realizing a narrow frame for the display substrate having the circular display area is provided.

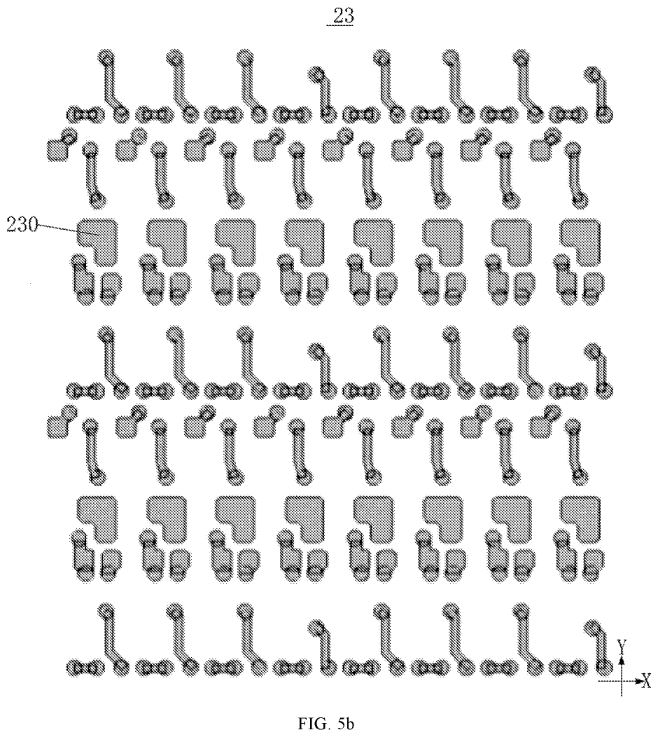

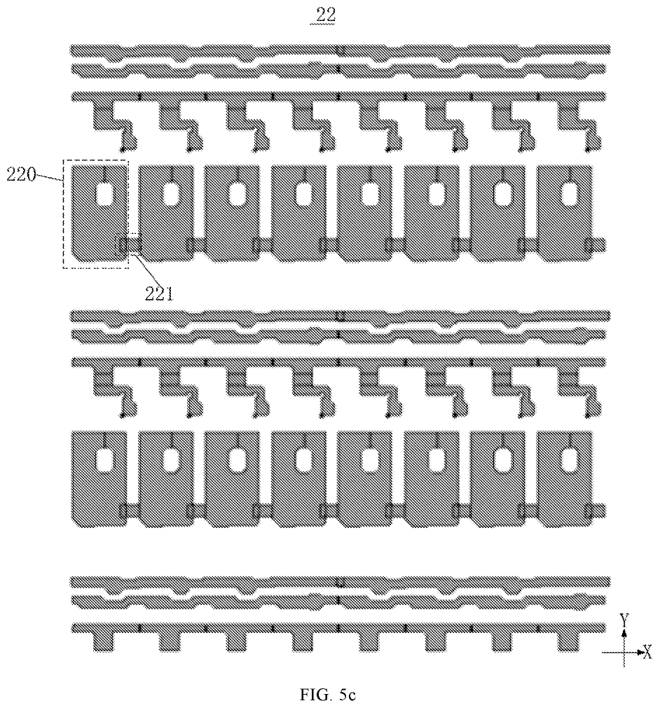

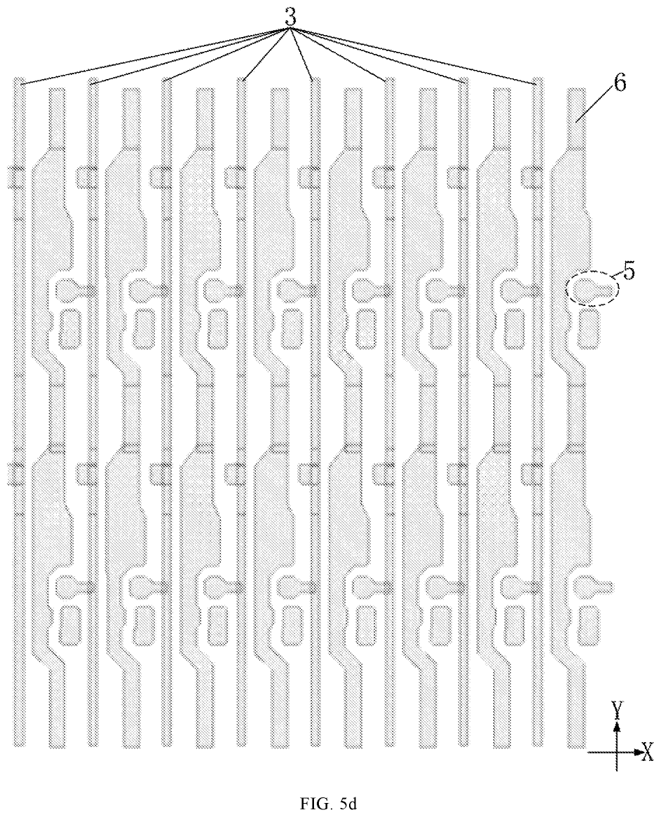

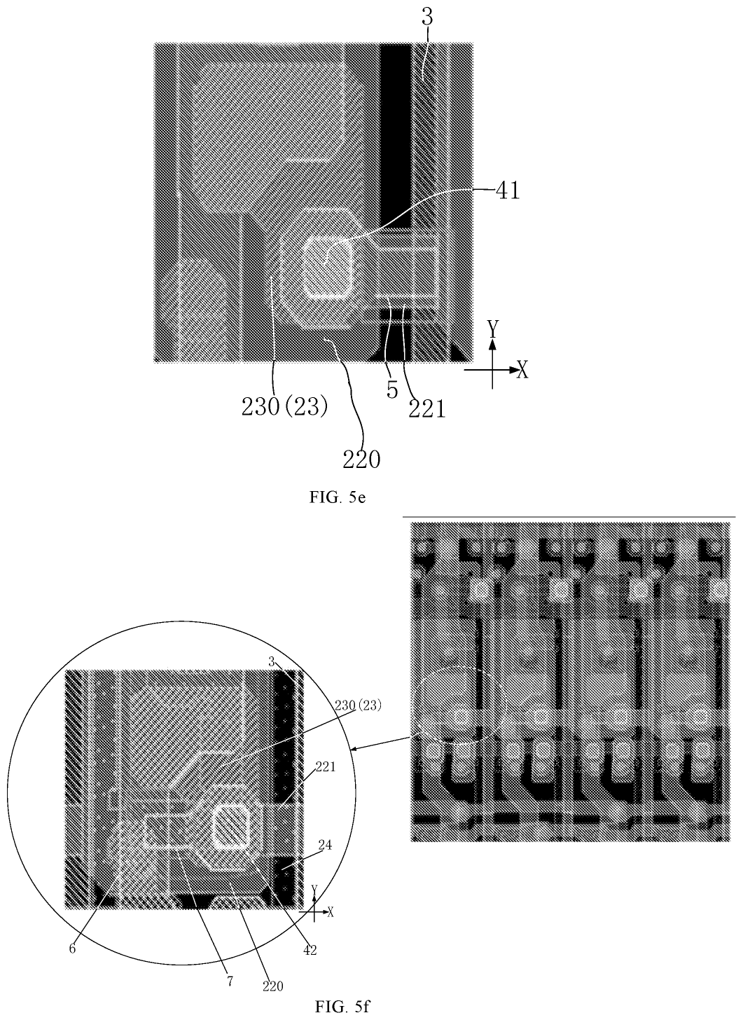

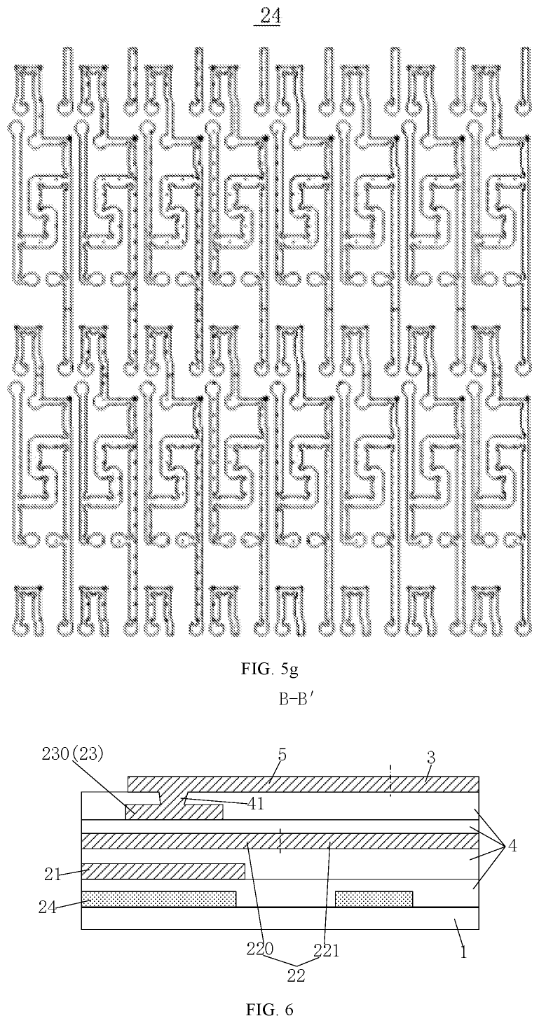

FIG. 5a is a schematic top view of a part of a structure of another display substrate according to an embodiment of the present disclosure. FIG. 5b illustrates a layout of a part of a third conductive layer according to an embodiment of the present disclosure. FIG. 5c illustrates another layout of a part of a second conductive layer according to an embodiment of the present disclosure. FIG. 5d illustrates another layout of a part of a conductive layer where data lines are located according to an embodiment of the present disclosure. FIG. 6 is a cross-sectional view of a structure taken along a line BB′ in FIG. 5a. Referring to FIG. 5a, FIG. 5b, FIG. 5c, FIG. 5d and FIG. 6, in some implementations, the display substrate further includes a third conductive layer 23 located between the second conductive layer 22 and the layer where the data lines 3 are located, and the third conductive layer 23 is insulated from the second conductive layer 22 and the data lines 3; the third conductive layer 23 includes a plurality of second patterns 230, orthographic projections of the second patterns 230 on the substrate 1 overlap with an orthographic projection of the second conductive layer 22 on the substrate 1, and at least part of the second patterns 230 are connected to the data lines 3.

An insulating layer 4 is arranged between any adjacent two of the third conductive layer 23, the second conductive layer 22 and the layer where the data lines 3 are located; and the data line 3 and the second pattern 230 corresponding to each other are connected to each other through a first via 41 formed in the insulating layer 4.

In the embodiment, the second patterns 230 connected to the data lines 3 and the second conductive layer 22 form capacitors in the area in which the orthographic projections of the second patterns 230 on the substrate 1 overlap with the orthographic projection of the second conductive layer 22 on the substrate 1, and the capacitors can be used as load compensation capacitors for compensating the loads of the data lines 3. In this way, on one hand, compensation capacitors for compensating the loads of the data lines 3 in the frame area of the display substrate can be reduced or eliminated, and further, the narrow frame, the ultra-narrow frame or the frameless design of the display substrate can be realized, and the market competitiveness of the display substrate can be improved; on the other hand, the loads of the data lines 3 connected to different numbers of pixel driving circuits 2 on the display substrate tend to be consistent with each other, thereby ensuring that the display effect is consistent at different positions of the display substrate, and ensuring the display effect of the display substrate.

In some implementations, referring to FIGS. 5a and 5c, the plurality of second patterns 230 are in a one-to-one correspondence with the third patterns 220 in the plurality of pixel driving circuits 2; and the orthographic projections of the second patterns 230 on the substrate 1 overlap with the orthographic projections of the third patterns 220 on the substrate 1.

In some implementations, each pixel driving circuit 2 includes a storage capacitor, and each pixel driving circuit 2 is provided with one third pattern 220; accordingly, the number of the second patterns 230 is the same as the number of the pixel driving circuits 2, i.e., each pixel driving circuit 2 corresponds to one second pattern 230. The second patterns 230 and the third patterns 220 form load compensation capacitors for compensating the loads of the data lines 3 connected to the second patterns 230 in the area where the orthographic projections of the second patterns 230 on the substrate 1 overlap with overlap with the orthographic projections of the third patterns 220 on the substrate 1.

In the embodiment, the data lines 3 with the loads to be compensated are connected to the second patterns 230; the data lines 3 with the loads not to be compensated are not connected to the second patterns 230.

In some implementations, a shape of each second pattern 230 includes a shape like an inverted letter “L”.

FIG. 5e is an enlarged top view of a location where a seventh pattern is disposed on a display substrate according to an embodiment of the present disclosure. Referring to FIGS. 5a, 5d, 5e, and 6, in some implementations, the display substrate further includes a plurality of seventh patterns 5, the seventh patterns 5 and the data lines 3 are located in a same layer, and the seventh patterns 5 are connected to the data lines 3; an insulating layer 4 is arranged between the layer where the data lines 3 are located and the third conductive layer 23; each seventh pattern 5 extends along the first direction X from the data line 3 connected to the seventh pattern 5 into an area in which orthographic projections of the seventh pattern 5 and the second pattern 230 corresponding to the seventh pattern 5 on the substrate 1 overlap with each other; and the seventh pattern 5 and the second pattern 230 corresponding to each other are connected to each other through a first via 41 formed in the insulating layer 4 in the area in which the orthographic projections of the seventh pattern 5 and the second pattern 230 on the substrate 1 overlap with each other.

In the embodiment, the seventh patterns 5 are only correspondingly disposed at positions at which the data lines 3 are to be connected to the second patterns 230; the seventh patterns 5 are configured such that the data lines 3 are connected to the second patterns 230; no seventh pattern is to be provided at any position at which the data line 3 is not to be connected to the second pattern 230.

FIG. 5f is an enlarged top view of a location where an eighth pattern is disposed on a display substrate according to an embodiment of the present disclosure. Referring to FIGS. 5d, 5f, and 6, in some implementations, the display substrate further includes a plurality of power supply lines 6 and a plurality of eighth patterns 7, the power supply lines 6 and the eighth patterns 7 are located in the same layer as the data lines 3, and each eighth pattern 7 is connected to the power supply line 6 corresponding thereto; the power supply lines 6 are sequentially arranged along the first direction X and each extend along the second direction Y; each eighth pattern 7 extends along the first direction X from the power supply line 6 connected to the eighth pattern 7 into an area in which orthographic projections of the eighth pattern 7 and the second pattern 230, corresponding to the eighth pattern 7, not connected to the data line 3 on the substrate 1 overlap with each other; and the eighth pattern 7 and the second pattern 230, corresponding to the eighth pattern 7, not connected to the data line 3 are connected to each other through a second via 42 formed in the insulating layer 4 in the area in which orthographic projections of the eighth pattern 7 and the second pattern 230 on the substrate 1 overlap with each other.

The eighth patterns 7 are provided such that the second patterns 230 not connected to the data lines 3 are connected to the power supply lines 6, thereby avoiding a signal jump transition caused by floating of the second patterns 230 not connected to the data lines 3.

FIG. 5g illustrates a layout of a part of an active layer in a pixel driving circuit according to an embodiment of the present disclosure. Referring to FIG. 5e, FIG. 5c, FIG. 5g and FIG. 6, in some implementations, the display substrate further includes an active layer 24 located between the substrate 1 and the first conductive layer 21, the active layer 24 and the first conductive layer 21 are insulated from each other; an orthographic projection of the active layer 24 on the substrate 1 partially overlaps with orthographic projections of the seventh patterns 5 and the data lines 3 on the substrate 1; the second conductive layer 22 further includes ninth patterns 221 connected to the third patterns 220, and orthographic projections of the ninth patterns 221 on the substrate 1 overlap with the area in which the orthographic projection of the active layer 24 on the substrate 1 overlaps with the orthographic projections of the seventh patterns 5 and the data lines 3 on the substrate 1.

The ninth patterns 221 can shield an overlap capacitor between a layer where the seventh patterns 5 and the data lines 3 are located and the active layer 24, so as to prevent the overlap capacitor from interfering with signals of the data lines 3.

In some implementations, an insulating layer 4 is disposed between the active layer 24 and the first conductive layer 21.

In some implementations, referring to FIGS. 5f, 5c and 5g, the orthographic projection of the active layer 24 on the substrate 1 partially overlaps with the orthographic projections of the data lines 3 on the substrate 1; the second conductive layer 22 further includes ninth patterns 221 connected to the third patterns 220, and each ninth pattern 221 extends along the first direction X from a position, at which the eighth pattern 7 and the second pattern 230 corresponding to each other are connected to each other, into an area in which the orthographic projections of the data line 3 on the substrate 1 overlap with the orthographic projection of the active layer 24 on the substrate 1, so that an orthographic projection of the ninth pattern 221 on the substrate 1 overlap with the area in which the orthographic projections of the data line 3 on the substrate 1 overlap with the orthographic projection of the active layer 24 on the substrate 1. That is, at a position at which the second pattern 230 and the data line 3 corresponding to each other are not connected to each other through the seventh pattern, the ninth patterns 221 are also disposed between the layer where the data lines 3 are located and the active layer 24.

The ninth patterns 221 can shield an overlap capacitor between the layer where the data lines 3 are located and the active layer 24, so as to prevent the overlap capacitor from interfering with signals of the data lines 3.

In some implementations, referring to FIG. 5c, each ninth pattern 221 is located between two adjacent third patterns 220 along the first direction X, and connects the two adjacent third patterns 220 along the first direction X.

In a second aspect, an embodiment of the present disclosure further provides a display panel, which includes the display substrate in the foregoing embodiments.

By adopting the display substrate in the foregoing embodiments, on one hand, compensation capacitors for compensating the loads of the data lines in the frame area of the display panel can be reduced or eliminated, and further, the narrow frame, the ultra-narrow frame or the frameless design of the display panel can be realized, and the market competitiveness of the display panel can be improved; on the other hand, the loads of the data lines connected to different numbers of pixel driving circuits on the display panel tend to be consistent with each other, thereby ensuring that the display effect is consistent at different positions of the display panel, and ensuring the display effect of the display panel.

In a third aspect, an embodiment of the present disclosure further provides a display apparatus, which includes the display panel in the foregoing embodiment.

By adopting the display panel in the foregoing embodiment, on one hand, the narrow frame, the ultra-narrow frame or the frameless design of the display apparatus can be realized, and the market competitiveness of the display apparatus can be improved; on the other hand, the display effect of the display apparatus is ensured.

The display apparatus provided by the embodiment of the present disclosure can be any product or component with a display function, such as an OLED panel, an OLED television, an OLED billboard, a display, a mobile phone, a navigator or the like.

It should be understood that the above embodiments are merely exemplary embodiments adopted to explain the principles of the present disclosure, and the present disclosure is not limited thereto. It will be apparent to ordinary skills in the art that various changes and modifications may be made without departing from the spirit and scope of the present disclosure, and such changes and modifications are considered falling within the scope of the present disclosure.

1. A display substrate, comprising:
a substrate;
a plurality of pixel driving circuits arranged in an array on the substrate; and
a plurality of data lines arranged in sequence along a first direction and each extending along a second direction on the substrate,
wherein each data line is connected to one column of pixel driving circuits;
at least part of the plurality of data lines are respectively connected to different numbers of pixel driving circuits;
the display substrate comprises a first conductive layer and a second conductive layer, and the first conductive layer, the second conductive layer and a layer where the plurality of data lines are located are sequentially arranged away from the substrate and insulated from each other;
the first conductive layer comprises a first pattern connected to the data lines; and
an orthographic projection of the second conductive layer on the substrate partially overlaps with an orthographic projection of the first pattern on the substrate; and/or
the display substrate further comprises a third conductive layer between the second conductive layer and the layer where the plurality of data lines are located, and the third conductive layer is insulated from the second conductive layer and the plurality of data lines; and
the third conductive layer comprises a plurality of second patterns, orthographic projections of the plurality of second patterns on the substrate overlap with an orthographic projection of the second conductive layer on the substrate, and at least part of the plurality of second patterns are connected to the data lines.

2. The display substrate of claim 1, wherein each of the plurality of pixel driving circuits comprises a storage capacitor,
the second conductive layer comprises a plurality of third patterns;
the first conductive layer further comprises a plurality of fourth patterns;
orthographic projections of the third patterns on the substrate at least partially overlap with orthographic projections of the fourth patterns on the substrate; each third pattern is common to an electrode plate of the storage capacitor; each fourth pattern is common to another electrode plate of the storage capacitor; and
the first pattern is between two adjacent fourth patterns in the first direction; the orthographic projections of the third patterns on the substrate at least partially overlap with the orthographic projection of the first pattern on the substrate.

3. The display substrate of claim 2, wherein the first pattern has a stripe shape, and a long side of the first pattern extends in the second direction.

4. The display substrate of claim 3, wherein the orthographic projection of the first pattern on the substrate overlaps with orthographic projections of the data lines on the substrate.

5. The display substrate of claim 3, wherein the first conductive layer further comprises a plurality of first signal lines;
the plurality of first signal lines are sequentially arranged along the second direction and each extend along the first direction;
the plurality of first signal lines spatially crosses the plurality of data lines; and
orthographic projections of the plurality of first signal lines on the substrate do not overlap with the orthographic projection of the first pattern on the substrate.

6. The display substrate of claim 3, wherein numbers of pixel driving circuits connected to different data lines are different from each other;
a load of the data line connected to a maximum number of pixel driving circuits is a target load;
a plurality of the first patterns are provided;
each data line without the target load is correspondingly connected to multiple first patterns;
an effective total length of the first patterns, connected to the data line without the target load, is proportional to a load to be compensated for the data line;
the effective total length of the first patterns is a sum of effective lengths of the first patterns; the effective length of each first pattern is a length of an area, in which orthographic projections of the first pattern and the third pattern corresponding to each other on the substrate overlap with each other, along the second direction;
the load to be compensated for the data line is a difference between the target load and an actual load of the data line; and
the actual load is a load formed by the pixel driving circuits connected to the data line.

7. The display substrate of claim 3, wherein the first conductive layer further comprises a fifth pattern, an orthographic projection of the fifth pattern on the substrate is located at ends of at least part of the plurality of data lines;
the second conductive layer further comprises a sixth pattern, and an orthographic projection of the sixth pattern on the substrate is located at ends of at least part of the plurality of data lines;
orthographic projections of the fifth pattern and the sixth pattern on the substrate overlap with each other; and
the fifth pattern or the sixth pattern is connected to the data lines.

8. The display substrate of claim 2, wherein the plurality of second patterns are in a one-to-one correspondence with the plurality of third patterns; and
orthographic projections of the second patterns on the substrate overlap with orthographic projections of the third patterns on the substrate.

9. The display substrate of claim 8, wherein each second pattern has a shape like an inverted letter “L”.

10. The display substrate of claim 8, further comprising a plurality of seventh patterns, wherein the plurality of seventh patterns and the plurality of data lines are located in a same layer, and the plurality of seventh patterns are connected to the data lines;
an insulating layer is arranged between the layer where the plurality of data lines are located and the third conductive layer;
each seventh pattern extends along the first direction from the data line connected to the seventh pattern into an area in which orthographic projections of the seventh pattern and the second pattern corresponding to each other on the substrate overlap with each other; and
the seventh pattern and the second pattern corresponding to each other are connected to each other through a first via in the insulating layer in the area in which the orthographic projections of the seventh pattern and the second pattern on the substrate overlap with each other.

11. The display substrate of claim 10, further comprising a plurality of power supply lines and a plurality of eighth patterns, wherein the plurality of power supply lines and the plurality of eighth patterns are located in the same layer as the plurality of data lines, and each eighth pattern is connected to the power supply line corresponding thereto;
the plurality of power supply lines are sequentially arranged along the first direction and each extend along the second direction;
each eighth pattern extends along the first direction from the power supply line connected to the eighth pattern into an area in which orthographic projections of the eighth pattern and the second pattern, corresponding to the eighth pattern, not connected to the data line on the substrate overlap with each other; and
the eighth pattern and the second pattern, corresponding to the eighth pattern, not connected to the data line are connected to each other through a second via in the insulating layer in the area in which the orthographic projections of the eighth pattern and the second pattern not connected to the data line on the substrate overlap with each other.

12. The display substrate of claim 10, further comprising an active layer between the substrate and the first conductive layer, wherein the active layer and the first conductive layer are insulated from each other;
an orthographic projection of the active layer on the substrate partially overlaps with orthographic projections of the plurality of seventh patterns and the plurality of data lines on the substrate; and
the second conductive layer further comprises ninth patterns connected to the third patterns, and orthographic projections of the ninth patterns on the substrate overlap with the area where the orthographic projection of the active layer on the substrate overlaps with the orthographic projections of the plurality of seventh patterns and the plurality of data lines on the substrate.

13. The display substrate of claim 11, further comprising an active layer between the substrate and the first conductive layer, wherein the active layer and the first conductive layer are insulated from each other;
an orthographic projection of the active layer on the substrate partially overlaps with orthographic projections of the plurality of data lines on the substrate; and
the second conductive layer further comprises ninth patterns connected to the third patterns, and each ninth pattern extends along the first direction from a position, in which the eighth pattern and the second pattern corresponding to each other are connected to each other, into an area in which the orthographic projections of the data lines on the substrate overlap with the orthographic projection of the active layer on the substrate, so that an orthographic projection of the ninth pattern on the substrate overlaps with the area in which the orthographic projections of the data lines on the substrate overlap with the orthographic projection of the active layer on the substrate.

14. The display substrate of claim 12 wherein each ninth pattern is between two adjacent third patterns along the first direction, and connects the two adjacent third patterns along the first direction.

15. A display panel, comprising the display substrate of claim 1.

16. A display apparatus, comprising the display panel of claim 15.

17. The display substrate of claim 4, wherein the first conductive layer further comprises a plurality of first signal lines;
the plurality of first signal lines are sequentially arranged along the second direction and each extend along the first direction;
the plurality of first signal lines spatially crosses the plurality of data lines; and
orthographic projections of the plurality of first signal lines on the substrate do not overlap with the orthographic projection of the first pattern on the substrate.

18. The display substrate of claim 4, wherein numbers of pixel driving circuits connected to different data lines are different from each other;
a load of the data line connected to a maximum number of pixel driving circuits is a target load;
a plurality of the first patterns are provided;
each data line without the target load is correspondingly connected to multiple first patterns;
an effective total length of the first patterns, connected to the data line without the target load, is proportional to a load to be compensated for the data line;
the effective total length of the first patterns is a sum of effective lengths of the first patterns; the effective length of each first pattern is a length of an area, in which orthographic projections of the first pattern and the third pattern corresponding to each other on the substrate overlap with each other, along the second direction;
the load to be compensated for the data line is a difference between the target load and an actual load of the data line; and
the actual load is a load formed by the pixel driving circuits connected to the data line.

19. The display substrate of claim 4, wherein the first conductive layer further comprises a fifth pattern, an orthographic projection of the fifth pattern on the substrate is located at ends of at least part of the plurality of data lines;
the second conductive layer further comprises a sixth pattern, and an orthographic projection of the sixth pattern on the substrate is located at ends of at least part of the plurality of data lines;
orthographic projections of the fifth pattern and the sixth pattern on the substrate overlap with each other; and
the fifth pattern or the sixth pattern is connected to the data lines.

20. The display substrate of claim 13, wherein each ninth pattern is between two adjacent third patterns along the first direction, and connects the two adjacent third patterns along the first direction.
